(19) United States
(12) Patent Application Publication
(10) Pub. No.: US 2025/0293081 A1
(43) Pub. Date: Sep. 18, 2025

(54) WAFER PLACEMENT TABLE

(71) Applicant: NGK INSULATORS, LTD., Nagoya-City (JP)

(72) Inventors: Taro USAMI, Ginan-Town (JP); Tatsuya KUNO, Nagoya-City (JP)

(73) Assignee: NGK INSULATORS, LTD., Nagoya-City (JP)

(21) Appl. No.: 18/903,285

(22) Filed: Oct. 1, 2024

Related U.S. Application Data
(63) Continuation of application No. PCT/JP2024/010541, filed on Mar. 18, 2024.

(51) Int. Cl. H01L 21/687

(52) U.S. Cl. CPC H01L 21/68785; H01L 21/68757

(57) ABSTRACT

A wafer placement table includes a resin layer joining a ceramic plate and a conductive plate. The ceramic plate has an insulative gas passage plug. The resin layer has a resin layer through portion that is larger than the insulative gas passage plug in plan view. The conductive plate has a gas introduction path communicating with the insulative gas passage plug via the resin layer through portion. A conductive film is provided in the lower surface of the ceramic plate and is larger than the resin layer through portion in plan view. A conductive connecting portion is provided in the gas introduction path and is smaller than the resin layer through portion in plan view. The conductive connecting portion electrically connects the conductive film and the conductive plate to each other and allows the gas to flow from the gas introduction path to the insulative gas passage plug.

### BACKGROUND OF THE INVENTION

### 1. Field of the Invention

The present invention is related to a wafer placement table.

### 2. Description of the Related Art

A known wafer placement table includes a ceramic plate having a wafer placement surface at its upper surface and a base plate joined to a lower surface of the ceramic plate and having a gas introduction path. According to PTL 1, a first porous portion and a second porous portion are provided in such a wafer placement table. The first porous portion has an insulating property and is disposed in a through hole of a ceramic plate. The second porous portion has an insulating property and is fitted into a recess provided on the ceramic plate side of the base plate so as to face the first porous portion. Gas supplied to a gas introduction path passes through the second porous portion and the first porous portion, flows into a space between the wafer placement surface and a wafer, and is used to cool an object. PTL 1 describes that the existence of the first porous portion and the second porous portion can suppress the occurrences of electrical discharge (arc discharge) ascribable to a plasma caused in processing the wafer while ensuring a flow rate of gas from the gas introduction path to the wafer placement surface. The base plate is formed of metal and bonded to the lower surface of the ceramic plate with a resin layer interposed therebetween. A communicating hole having a larger diameter than that of the through hole of the ceramic plate is provided at a position in the resin layer facing the through hole of the ceramic plate.

### CITATION LIST

### Patent Literature

PTL 1: JP 2020-72262 A

### SUMMARY OF THE INVENTION

However, even when the insulative second porous portion is provided as in PTL 1, electrical discharge may occur around an end portion of the first porous portion on the base plate side. Furthermore, when the resin layer interferes with the first and second porous portions, a gas passage property of these may be degraded.

The present invention has been made to solve such problems, and a main object of the present invention is to suppress electrical discharge in a space on a lower surface side of an insulative gas passage plug while maintaining a gas passage property in a good state.

According to the present invention, the following technique is adopted to achieve the above-described main purpose.

[1] A wafer placement table according to the present invention includes a ceramic plate having a wafer placement surface at an upper surface thereof, the ceramic plate including an electrode therein, a conductive plate provided on a lower surface of the ceramic plate, a resin layer joining the ceramic plate and the conductive plate to each other, an insulative gas passage plug provided in a ceramic plate through portion extending through the ceramic plate, the insulative gas passage plug allowing gas to pass therethrough in an up-down direction, a resin layer through portion provided at a position facing the insulative gas passage plug in the resin layer so as to extend through the resin layer, the resin layer through portion being larger than the insulative gas passage plug in plan view, a gas introduction path provided in the conductive plate, the gas introduction path communicating with the insulative gas passage plug via the resin layer through portion, a conductive film provided at a position facing the resin layer through portion in the lower surface of the ceramic plate, the conductive film being larger than the resin layer through portion in plan view, the conductive film allowing the gas to flow from the gas introduction path to the insulative gas passage plug, and a conductive connecting portion provided in the gas introduction path, the conductive connecting portion being smaller than the resin layer through portion in plan view, the conductive connecting portion electrically connecting the conductive film and the conductive plate to each other, the conductive connecting portion allowing the gas to flow from the gas introduction path to the insulative gas passage plug.

In this wafer placement table, the resin layer through portion is larger than the insulative gas passage plug and the conductive connecting portion in plan view. Thus, interference of the resin layer with the insulative gas passage plug or the conductive connecting portion can be prevented, and a gas passage property of these components can be maintained in a good state. Furthermore, the conductive film, the potential of which becomes the same as the potential of the conductive plate via the conductive connecting portion, is larger than the resin layer through portion in plan view. Thus, the potential difference is unlikely to occur in the entirety of a space on a lower surface side of the insulative gas passage plug, and accordingly, electrical discharge in this space can be suppressed.

Although the present invention may be described with the terms such as up and down, left and right, and front and back herein, only the relative relationships are described with up and down, left and right, and front and back. Thus, when the orientation of the wafer placement table is changed, up and down may change to left and right or left and right may change to up and down. These cases are also included in the technical scope of the present invention.

[2] In the above-described wafer placement table (the wafer placement table described in [1]), a plurality of the ceramic plate through portions may be provided in the ceramic plate, a plurality of the insulative gas passage plugs may be respectively provided in the plurality of ceramic plate through portions, a plurality of the gas introduction paths may be provided at positions that respectively face the plurality of insulative gas passage plugs, a plurality of the resin layer through portions may be provided at positions that respectively face the plurality of insulative gas passage plugs, a plurality of the conductive films may be provided at positions respectively face the plurality of resin layer through portions, a plurality of the conductive connecting portions may be respectively provided in the plurality of the gas introduction paths, and any one of the plurality of conductive films may be electrically connected to at least one other conductive film. Thus, even when a plug lower surface film provided on the lower surface of the insulative gas passage plugs and an annular film around the plug lower surface film are separated from each other in the conductive film, electrical discharge in the space on the lower surface side of the insulative gas passage plug can still be suppressed. The reason for this is that the potential of the plug lower surface film becomes the same as the potential of the conductive plate via the conductive connecting portion, and the potential of the annular film becomes the same as the potential of the conductive plate via the other conductive film electrically connected to the annular film.

[3] In the above-described wafer placement table (the wafer placement table described in [2]), the any one of the plurality of conductive films may be electrically connected to the at least one other conductive film via a conductive link provided on the lower surface of the ceramic plate. In this way, the conductive link and the conductive films can be simultaneously formed on the lower surface of the ceramic plate in a single step.

[4] In the above-described wafer placement table (the wafer placement table described in [2]), in at least one of the plurality of conductive films, a plug lower surface film provided on a lower surface of a corresponding one of the plurality of insulative gas passage plugs and an annular film provided at an outer circumference of the plug lower surface film may be separated from each other, and the annular film may be electrically connected to the conductive plate via the at least one other conductive film. In this way, even when the conductive film is separated into the plug lower surface film and the annular film, electrical discharge in the space on the lower surface side of the insulative gas passage plug can still be suppressed. The reason for this is that the potential of the plug lower surface film becomes the same as the potential of the conductive plate via the conductive connecting portion, and the potential of the annular film becomes the same as the potential of the conductive plate via the other conductive film electrically connected to the annular film.

[5] In the above-described wafer placement table (the wafer placement table described in any one of [1] to [4]), the conductive connecting portion may be a different member from the conductive plate. In this way, ease of the manufacture of the wafer placement table increases compared to the case where, for example, the conductive connecting portion and the conductive plate are a one-piece member instead of being the different members.

[6] In the above-described wafer placement table (the wafer placement table described in [5]), the conductive connecting portion may include a member having stretchability, and the member having stretchability may be disposed in a compressed state between a lower surface of the insulative gas passage plug and the conductive plate. In this way, ease of maintaining of electrical contact between the insulative gas passage plug and the conductive plate increases.

[7] In the above-described wafer placement table (the wafer placement table described in any one of [1] to [6]), the insulative gas passage plug may be a porous body, or the insulative gas passage plug may be a dense body having a helical gas passage or a zigzag gas passage therein. In this way, electrical discharge is unlikely to occur also when the gas passes through the insulative gas passage plug.

### BRIEF DESCRIPTION OF THE DRAWINGS

FIG. 1 is a plan view of a wafer placement table 10.

FIG. 2 is a sectional view taken along line A-A illustrated in FIG. 1.

FIG. 3 is an enlarged sectional view of part of FIG. 2.

FIG. 4 is a bottom view of a ceramic plate 20.

FIGS. 5A to 5H include diagrams of steps of manufacturing the wafer placement table 10.

FIGS. 6A to 6C include diagrams of steps of replacing a plug 50 with a plug 50X.

FIG. 7 is a bottom view of the ceramic plate 20 after the plug 50 has been replaced with the plug 50X.

FIG. 8 is a bottom view of another example of the ceramic plate 20.

FIG. 9 is a bottom view of another example of the ceramic plate 20.

FIG. 10 is a bottom view of another example of the ceramic plate 20.

### DETAILED DESCRIPTION OF THE INVENTION

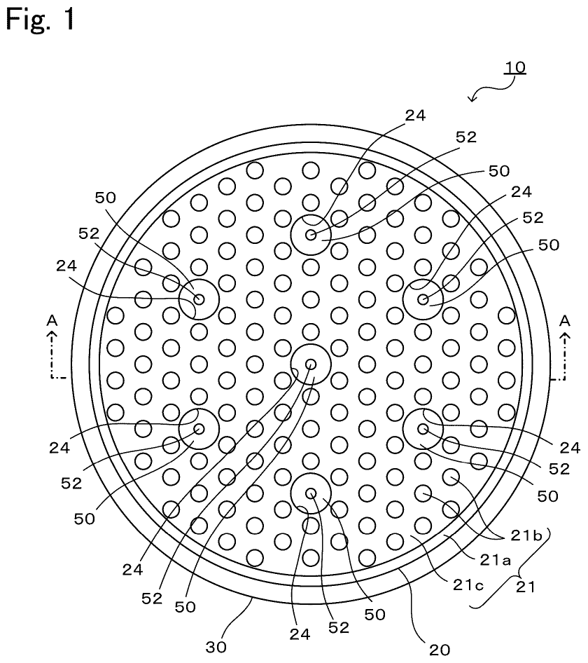

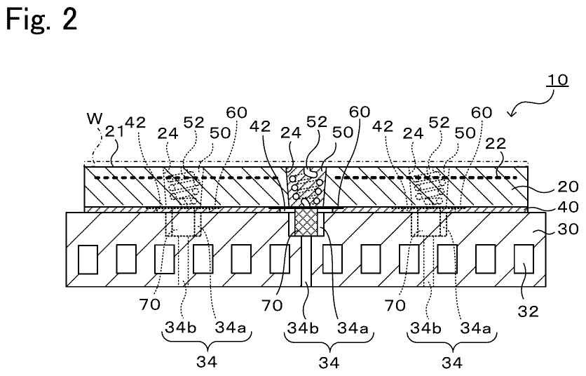

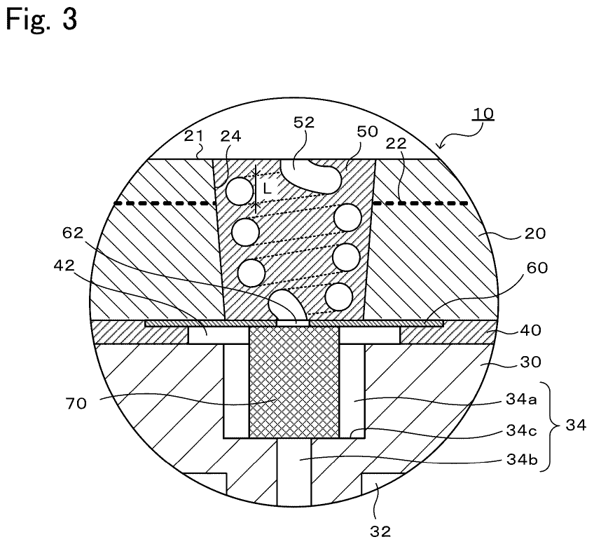

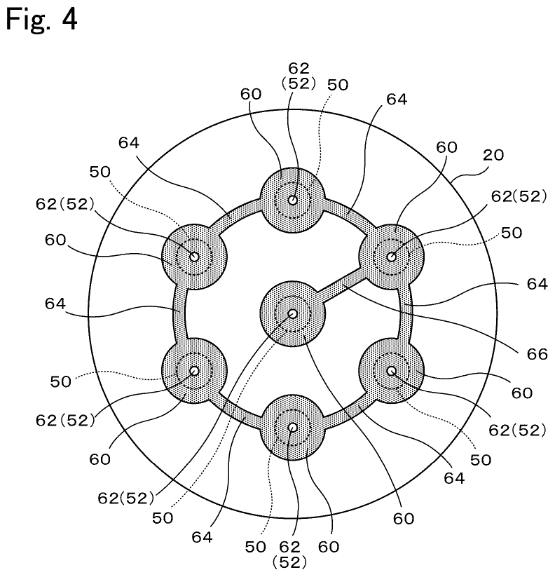

Next, a preferred embodiment of the present invention is described below with reference to the drawings. FIG. 1 is a plan view of a wafer placement table 10. FIG. 2 is a sectional view taken along line A-A illustrated in FIG. 1. FIG. 3 is an enlarged sectional view of part of FIG. 2. FIG. 4 is a bottom view of a ceramic plate 20 (including conductive films 60 and conductive links 64 and 66). For convenience, a seal band 21a, circular small projections 21b, and a reference surface 21c of a wafer placement surface 21 are omitted from FIGS. 2 and 3.

As illustrated in FIG. 2, the wafer placement table 10 includes the ceramic plate 20, a conductive plate 30, a resin layer 40, plugs 50, resin layer through holes 42, gas introduction paths 34, the conductive films 60, and contact members 70.

The ceramic plate 20 is a disc (for example, having a diameter of 300 mm and a thickness of 5 mm) formed of ceramic such as an alumina sintered body or an aluminum nitride sintered body. An upper surface of the ceramic plate 20 serves as the wafer placement surface 21 on which a wafer W is to be placed. The ceramic plate 20 includes an electrode 22 disposed therein. As illustrated in FIG. 1, the annular seal band 21a is formed along an outer edge of the wafer placement surface 21 of the ceramic plate 20, and a plurality of the circular small projections 21b are formed inside the seal band 21a throughout the wafer placement surface 21. The seal band 21a and the circular small projections 21b have the same height which is, for example, from a few or several um to a few or several tens um. The electrode 22 is a planar mesh electrode used as an electrostatic electrode and connected to an external direct-current power source via a power supply member (not illustrated). A low-pass filter may be disposed at a midpoint in the power supply member. The power supply member is electrically insulated from the conductive plate 30. When a direct current is applied to the electrode 22, the wafer W is attracted and secured to the wafer placement surface 21 (specifically, an upper surface of the seal band 21a and upper surfaces of the circular small projections 21b) by an electrostatic attraction force. When the application of the direct current is stopped, the attraction and securing of the wafer W to the wafer placement surface 21 are stopped. A portion of the wafer placement surface 21 where the seal band 21a or the circular small projections 21b are not provided is referred to as the reference surface 21c.

The conductive plate 30 is a disc (a disc having a diameter that is the same as or greater than the diameter of the ceramic plate 20) having a good thermal conductivity. A refrigerant flow path 32 through which a refrigerant circulates is formed in the conductive plate 30. The refrigerant flowing through the refrigerant flow path 32 is preferably a liquid and preferably has electrical insulation. Examples of an electrically insulative liquid include, for example, a fluorine inert liquid and the like. In plan view, the refrigerant flow path 32 is formed in a one-stroke pattern from one end (inlet) to another end (outlet) throughout the conductive plate 30. A supply port and a collection port of an external refrigerant device (not illustrated) are respectively connected to the one end and the other end of the refrigerant flow path 32. The refrigerant supplied from the supply port of the external refrigerant device to the one end of the refrigerant flow path 32 passes through the refrigerant flow path 32. Then, the refrigerant returns from the other end of the refrigerant flow path 32 to the collection port of the external refrigerant device and undergoes temperature adjustment. Then, the refrigerant is supplied to the one end of the refrigerant flow path 32 again from the supply port. The conductive plate 30 is connected to a radio-frequency (RF) power source and used as an RF electrode.

Examples of the material of the conductive plate 30 include, for example, a metal material, a metal-ceramic composite, and the like. Examples of the metal material include Al, Ti, Mo, and an alloy of any of these. Examples of the metal-ceramic composite include a metal matrix composite (MMC), a ceramic matrix composite (CMC), and the like. Specific examples of such a composite include a material including Si, SiC, and Ti (also referred to as SisiCTi), a material formed by impregnating a Sic porous body with Al and/or Si, an Al₂O₃-TiC composite, and the like. Preferably, a material having a coefficient of thermal expansion close to that of the material of the ceramic plate 20 is selected as the material of the conductive plate 30.

The resin layer 40 is an electrically insulative layer and joins a lower surface of the ceramic plate 20 and an upper surface of the conductive plate 30 together. The resin layer 40 may be formed of, for example, a silicone-resin bond, an acrylic-resin bond, or a bonding sheet.

Examples of the bonding sheet include, for example, a sheet in which acrylic resin layers are provided on both surfaces of a polypropylene core, a sheet in which silicone resin layers are provided on both surfaces of a polyimide core, a sheet formed only of epoxy resin, and the like. The reason for not using a metal layer but using the resin layer 40 to join the ceramic plate 20 and the conductive plate 30 together is to respond demand for mildly cooling the wafer W with the conductive plate 30.

The plugs 50 allow gas to pass therethrough in an up-down direction and are provided in plug reception holes 24 that extend through the ceramic plate 20 in the up-down direction. The plug reception holes 24 are examples of a ceramic plate through portion. The plugs 50 are examples of an insulative gas passage plug. Although the plug reception holes 24 extend through the electrode 22 in the up-down direction, the electrode 22 is not exposed in inner circumferential surfaces of the plug reception holes 24. Each of the plug reception holes 24 is a tapered hole having an inverted truncated conical space in which the area of an upper opening is greater than the area of a lower opening. In plan view, the plug reception holes 24 are provided at a plurality of positions in the ceramic plate 20 (for example, as illustrated in FIG. 1, a central portion and a plurality of positions equally spaced in the circumferential direction in the ceramic plate 20, a total of seven positions in FIG. 1). Each of the plugs 50 is provided in a corresponding one of the plurality of plug reception holes 24. The plugs 50 have an inverted truncated conical shape and are formed of insulative dense ceramic or insulative porous ceramic (for example, the same material as the material of the ceramic plate 20).

Each of the plugs 50 has a helical gas passage 52 extending from a lower surface to an upper surface of the plug 50. To suppress electrical discharge in the gas passage 52, a length L (FIG. 3) inside the gas passage 52 in the up-down direction is preferably set to smaller than or equal to 1 mm, more preferably set to smaller than or equal to 0.5 mm, and even more preferably set to smaller than or equal to 0.2 mm. Electrical discharge occurs when electrons generated due to ionization of a gas (for example, a helium gas) in the gas passage 52 accelerate and collide with other helium. However, when the length in the gas passage 52 in the up-down direction is smaller than or equal to 1 mm, ionized electrons do not sufficiently accelerate. Thus, such electrical discharge can be suppressed. When ensuring of a flow rate of the gas is considered, the length L is preferably greater than or equal to 0.1 mm. The plug 50 is secured to the plug reception hole 24. Specifically, an outer circumferential surface of the plug 50 may be bonded to the inner circumferential surface of the plug reception hole 24, or a male screw portion provided in the outer circumferential surface of the plug 50 may be screwed into a female screw portion provided in the inner circumferential surface of the plug reception hole 24. As a different form, the plug 50 may have a tapered shape to be engaged with the plug reception hole 24. In this case, the plug 50 is press-fitted into the plug reception hole 24 so as to be engaged with the plug reception hole 24. From the viewpoint of improving accuracy of positioning of the plug 50 in the height direction in press-fitting of the plug 50 downward into the plug reception hole 24, the taper angle may be, for example, 70° to 87°. The upper surface of the plug 50 is flush with the reference surface 21c of the wafer placement surface 21. The lower surface of the plug 50 is flush with the lower surface of the ceramic plate 20.

The resin layer through holes 42 are examples of a resin layer through portion and provided at positions in the resin layer 40 facing the plugs 50 so as to extend through the resin layer 40. In plan view, each of the resin layer through holes 42 is greater than the lower surface of the plug 50. Specifically, the diameter of the resin layer through hole 42 is greater than the diameter of the lower surface of the plug 50. Each of the resin layer through holes 42 is provided at a position facing a corresponding one of the plurality of plugs 50.

The gas introduction paths 34 are provided in the conductive plate 30. Each of the gas introduction paths 34 is provided at a position facing a corresponding one of the plurality of plugs 50. The gas introduction path 34 communicates with the helical gas passage 52 of the plug 50 via the resin layer through hole 42. Here, the gas introduction paths 34 are provided so as to extend through the conductive plate 30 in the up-down direction. The gas introduction paths 34 each have a large diameter portion 34a and a small diameter portion 34b. The large diameter portion 34a is a cylindrical space provide in an upper portion of the gas introduction path 34. The small diameter portion 34b is a tubular space provided below the large diameter portion 34a.

Each of the conductive films 60 is provided so as to have a circular shape at a position in the lower surface of the ceramic plate 20 facing a corresponding one of the plurality of resin layer through holes 42. In plan view, the conductive film 60 is greater than the resin layer through hole 42. Specifically, the diameter of the conductive film 60 is greater than the diameter of the resin layer through hole 42. Accordingly, the conductive film 60 covers the lower surface of the plug 50 and a region around the lower surface of the plug 50 on the lower surface of the ceramic plate 20. Furthermore, an outer circumferential portion of the conductive film 60 is interposed between the ceramic plate 20 and the resin layer 40. The conductive film 60 has a through hole 62 that allows the gas to flow from the gas introduction path 34 to the gas passage 52 of the plug 50. The conductive film 60 is formed by, for example, sputtering, electroless plating, or the like. Any one of a plurality of conductive films 60 is electrically connected to at least one of the other conductive films 60. As illustrated in FIG. 4, according to the present embodiment, two adjacent conductive films 60 of six conductive films 60 arranged in the circumferential direction on the lower surface of the ceramic plate 20 are electrically connected to each other via an arc-shaped conductive link 64. The conductive link 64 may have a linear shape instead of an arc shape. Furthermore, a conductive film 60 provided at the center of the lower surface of the ceramic plate 20 is electrically connected to one of the other conductive films 60 via a linear conductive link 66. The conductive film 60 at the center may be electrically connected to two or more of the other conductive films 60. As is the case with the conductive films 60, the conductive links 64 and 66 are provided on the lower surface of the ceramic plate 20.

The contact members 70 are examples of a conductive connecting portion. Each of the contact members 70 is provided in a corresponding one of a plurality of large diameter portions 34a. The contact member 70 has conductivity, electrically connects the conductive film 60 and the conductive plate 30 to each other, and allows the gas to flow from the gas introduction path 34 to the gas passage 52 of the plug 50. In plan view, the contact member 70 is smaller than the resin layer through hole 42. Specifically, the diameter of the contact member 70 is smaller than the diameter of resin layer through hole 42. The contact members 70 are provided as different members from the conductive plate 30. A lower surface of the contact member 70 is in contact with a step surface 34c of the gas introduction path 34 of the conductive plate 30, and an upper surface of the contact member 70 is in contact with the conductive film 60. According to the present embodiment, the contact member 70 is a substantially cylindrical member having a circular upper surface.

Examples of the contact member 70 include, for example, a conductive mesh and an aggregated conductive fiber (steel wool, carbon felt, and the like). Examples of the material of the contact member 70 include, for example, a metal material, carbon, and the like. Examples of the metal material include Al, Ti, Mo, an alloy of any of these, steel, and the like. When the contact member 70 is the conductive mesh, the aperture width is from 0.062 mm (250 meshes) to 0.154 mm (100 meshes). The contact member 70 preferably has stretchability in the up-down direction. For example, the conductive mesh and the aggregated conductive fiber having been described above are examples of a member having stretchability in the up-down direction. The contact member 70 is disposed in a state in which the contact member 70 is compressed between the lower surface of the plug 50 and the step surface 34c of the gas introduction path 34 of the conductive plate 30.

Next, an example of usage of the wafer placement table 10 configured as above is described. First, the wafer W is placed on the wafer placement surface 21 in a state in which the wafer placement table 10 is installed in a chamber (not illustrated). The inside of the chamber is adjusted to a predetermined degree of vacuum by reducing the pressure with a vacuum pump, and the electrostatic attraction force is generated by applying the direct-current voltage to the electrode 22 of the ceramic plate 20 so as to attract and secure the wafer W to the wafer placement surface 21 (specifically, the upper surface of the seal band 21a and the upper surfaces of the circular small projections 21b). Next, the inside of the chamber is set into a reactant gas atmosphere of a predetermined pressure (for example, a few or several tens to a few or several hundreds Pa). In this state, an RF voltage is applied across an upper electrode (not illustrated) provided in a ceiling portion of the chamber and the conductive plate 30 of the wafer placement table 10 so as to generate plasma. A surface of the wafer W is processed with the generated plasma. The refrigerant circulates through the refrigerant flow path 32 of the conductive plate 30. A backside gas is introduced into the gas introduction paths 34 from a gas bombe (not illustrated). A thermal conduction gas (for example, a He gas or the like) is used as the backside gas. The backside gas having been introduced into the gas introduction paths 34 passes through the contact members 70 and the gas passages 52 of the plugs 50, is supplied to a space between a back surface of the wafer W and the reference surface 21c of the wafer placement surface 21, and is sealed. Due to the existence of this backside gas, the thermal conduction between the wafer W and the ceramic plate 20 is efficiently performed.

During the use of the wafer placement table 10, the provision of the helical gas passages 52 in the plugs 50 can suppress electrical discharge in the gas passages 52. For example, when gas passages that linearly extend in the up-down direction are provided instead of the helical gas passages 52, electrons generated due to ionization of the gas molecules caused by application of the RF voltage accelerate and collide with other gas molecules. This causes the electrical discharge. However, according to the present embodiment, the gas passages 52 have a helical shape, and the length L in the gas passages 52 in the up-down direction is short. Accordingly, the electrons collide with the other gas molecules before the electrons sufficiently accelerate (that is, before the electrons have sufficient energy). This can suppress electrical discharge occurring in the gas passages 52.

Furthermore, the conductive films 60 provided on lower surfaces of the plugs 50 are electrically connected to the conductive plate 30 via the contact members 70. That is, the potential of the conductive films 60 is the same as the potential of the conductive plate 30. This suppresses the occurrences of a potential difference in the entirety of the large diameter portions 34a that are spaces on the lower surface side of the plugs 50. Accordingly, the occurrences of electrical discharge in the large diameter portions 34a can be suppressed.

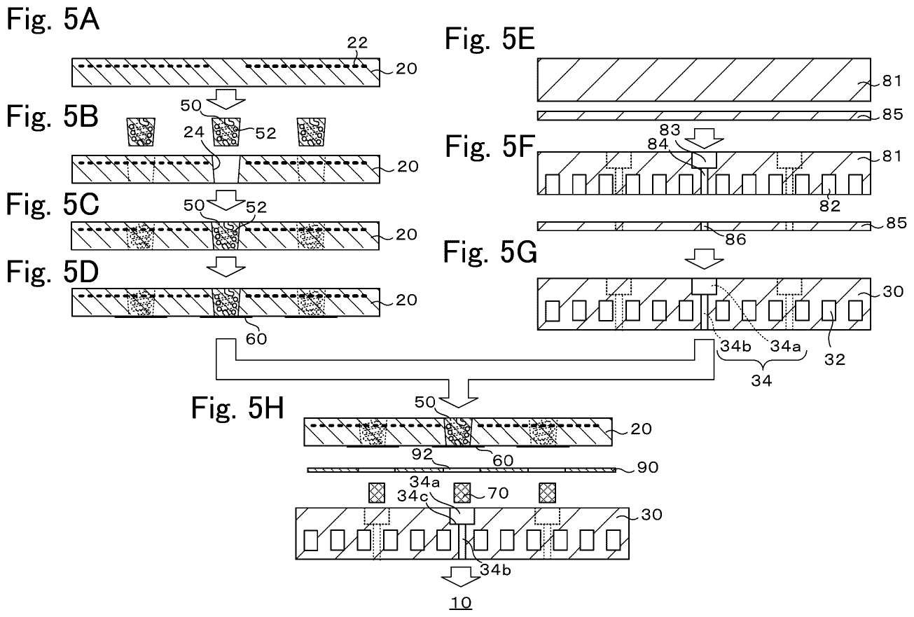

Next, an example of the manufacture of the wafer placement table 10 is described with reference to FIGS. 5A to 5H. FIGS. 5A to 5H include diagrams of steps of manufacturing the wafer placement table 10. Here, the case of creating the conductive plate 30 with the MMC is exemplified. First, the ceramic plate 20 including the electrode 22 disposed therein is prepared (FIG. 5A). For example, a molded body of ceramic powder including the electrode 22 disposed therein is created, and the molded body is hot-press fired to obtain the ceramic plate 20. The plug reception holes 24 are formed in the ceramic plate 20 (FIG. 5B). The plug reception holes 24 are formed so as to extend through the ceramic plate 20 in the up-down direction and avoid the electrode 22. Then, the plugs 50 having been created in advance are secured to the plug reception holes 24 of the ceramic plate 20 (FIG. 5C). The plugs 50 including the helical gas passages 52 can be created by, for example, utilizing a 3D printer. Then, the conductive films 60 and the conductive links 64 and 66 are formed on the lower surface of the ceramic plate 20 by sputtering or electroless plating (FIG. 5D). The conductive links 64 and 66 are omitted from FIG. 5D.

In parallel with this, two MMC disc members 81 and 85 are prepared (FIG. 5E). Grooves and holes are appropriately formed in the MMC disc members 81 and 85 by machining (FIG. 5F). Specifically, grooves 82, which finally become the refrigerant flow path 32, are formed in a lower surface of the upper MMC disc member 81. Furthermore, recesses 83, which finally become the large diameter portions 34a of the gas introduction paths 34, are formed in an upper surface of the MMC disc member 81. In addition, tubular spaces 84, which are to become parts of the small diameter portions 34b, are formed in a bottom surface of the recesses 83. Furthermore, tubular spaces 86, which finally become parts of the small diameter portions 34b, are formed in the lower MMC disc member 85. When the ceramic plate 20 is formed of alumina, the MMC disc members 81 and 85 are preferably formed of SisiCTi or AlSiC. The reason for this is that the coefficient of thermal expansion of the alumina and coefficient of thermal expansion of the SiSiCTi or AlSiC can be made to be substantially the same.

The disc members formed of SisiCTi can be created, for example, as follows. First, silicon carbide, metal Si, and metal Ti are mixed to create a powder mixture. Next, the obtained powder mixture is subjected to uniaxial compaction to create a discoidal molded body. The created molded body is subjected to hot-press sintering in an inert atmosphere to obtain the disc member formed of SiSiCTi.

Then, the upper MMC disc member 81 and the lower MMC disc member 85 are joined together by thermal compression bonding (TCB) to obtain the conductive plate 30 (FIG. 5G). After the TCB, the recesses 83 become the large diameter portions 34a, the tubular spaces 84 and 86 become the small diameter portions 34b, and the grooves 82 become the refrigerant flow path 32. Then, the contact members 70 having been created in advance are disposed on bottom surfaces (step surfaces 34c) of the large diameter portions 34a of the conductive plate 30. Then, a bonding sheet 90 is sandwiched between the lower surface of the ceramic plate 20 illustrated in FIG. 5D and the upper surface of the conductive plate 30 to obtain a laminated body. The laminated body is heated while being pressed to bond the ceramic plate 20 and the conductive plate 30 to each other with the resin layer 40 interposed therebetween (FIG. 5H). Through holes 92, which finally become the resin layer through holes 42, are formed in the bonding sheet 90 in advance. After that, when the entire shape is adjusted, the wafer placement table 10 is obtained.

In the wafer placement table 10 having been described in detail, the resin layer through holes 42 are larger than the plugs 50 and the contact members 70 in plan view. Thus, interference of the resin layer 40 with the plugs 50 or the contact members 70 can be prevented, and the gas passage property of these components can be maintained in a good state. Furthermore, the conductive films 60, the potential of which becomes the same as the potential of the conductive plate 30 via the contact members 70, are larger than the resin layer through holes 42 in plan view. Thus, the potential difference is unlikely to occur in the entirety of the spaces on the lower surface side of the plugs 50 (the large diameter portions 34a of the gas introduction paths 34), and accordingly, electrical discharge in those spaces can be suppressed. In the wafer placement table 10, this allows the power of the RF power source connected to the conductive plate 30 to increase compared to the case where insulative porous members exist instead of the contact members 70. Furthermore, the gas pressure of the backside gas can be increased so as to further increase efficiency of the thermal conduction between the wafer W and the ceramic plate 20.

Furthermore, the plurality of plug reception holes 24 are provided in the ceramic plate 20. Each of the plugs 50 is provided in a corresponding one of the plurality of plug reception holes 24. Each of the gas introduction paths 34 is provided at a position facing a corresponding one of the plurality of plugs 50. Each of the resin layer through holes 42 is provided at a position facing a corresponding one of the plurality of plugs 50. Each of the conductive films 60 is provided at a position facing a corresponding one of the plurality of resin layer through holes 42. Each of the contact members 70 is provided in a corresponding one of a plurality of the gas introduction paths 34. Any one of the plurality of conductive films 60 is electrically connected to at least one of the other conductive films 60. Thus, even when plug lower surface films provided on the lower surfaces of the plugs 50 and annular films around the plug lower surface films are separated from each other in the conductive films 60, electrical discharge in the spaces on the lower surface side of the plugs 50 (the large diameter portions 34a) can still be suppressed. This will be further described in detail below.

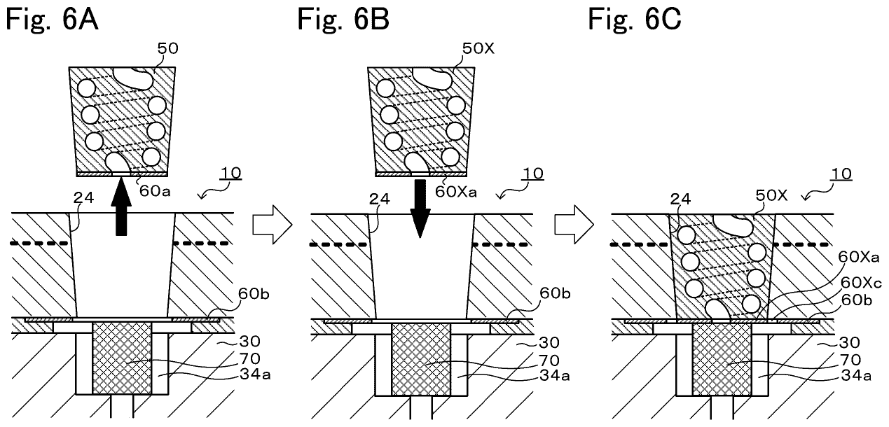

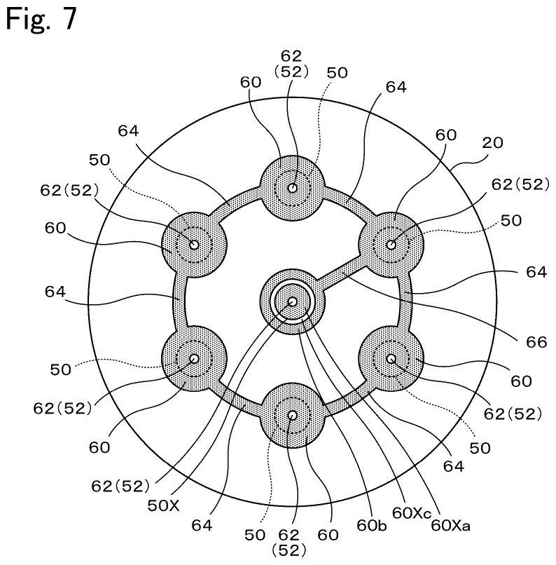

For example, it is assumed that, in the wafer placement table 10, a plug 50 disposed at the center of the ceramic plate 20 is required to be replaced with a new plug 50X. FIGS. 6A to 6C include diagrams of steps of replacing the plug 50 with the plug 50X. FIG. 7 is a bottom view of the ceramic plate 20 after the plug 50 has been replaced with the plug 50X. In this case, first, the attached plug 50 is pulled upward (FIG. 6A). A plug lower surface film 60a of the conductive film 60 adheres to the pulled plug 50. An annular film 60b remains around the plug reception hole 24 in the wafer placement table 10 from which the plug 50 has been pulled. Then, the new plug 50X is prepared (FIG. 6B). A plug lower surface film 60Xa is formed in advance on a lower surface of this plug 50X by sputtering or the like. This plug 50X is secured to the vacant plug reception hole 24. Thus, the plug 50X of the wafer placement table 10 is reworked (FIG. 6C). In the wafer placement table 10 in which the plug 50X has been reworked, a ring-shaped gap 60Xc may be formed between the plug lower surface film 60Xa of the plug 50X and the annular film 60b around the plug lower surface film 60Xa. In this case, the plug lower surface film 60Xa and the annular film 60b are not electrically connected to each other. In this case, the potential of the plug lower surface film 60Xa becomes the same as the potential of the conductive plate 30 via the contact member 70. Furthermore, the potential of the annular film 60b becomes the same as the potential of the conductive plate 30 via another conductive film 60 electrically connected to the annular film 60b via the conductive link 66 (FIG. 7). Thus, also in such a case, the potential difference is still unlikely to occur in the entirety of the spaces on the lower surface side of the plugs 50 (the large diameter portions 34a), and electrical discharge in those spaces can be suppressed. Although the replacement of the plug 50 disposed at the center of the ceramic plate 20 has been described herein, this is similarly applied to replacement of other plugs 50. FIGS. 6C and 7 is an embodiment of claim 4.

Furthermore, the conductive links 64 and 66 are provided on the lower surface of the ceramic plate 20. Accordingly, the conductive links 64 and 66 and the conductive films 60 can be simultaneously formed on the lower surface of the ceramic plate 20 in a single step.

Furthermore, the contact members 70 are different members from the conductive plate 30. Accordingly, ease of the manufacture of the wafer placement table 10 increases compared to the case where the contact member 70 and the conductive plate 30 are a one-piece component.

The contact members 70 have stretchability in the up-down direction, and are disposed in a state in which the contact members 70 are compressed between the plugs 50 and the conductive plate 30. This increases ease of maintaining of contact between the plugs 50 and the conductive plate 30.

Furthermore, the plugs 50 each have the helical gas passage 52 therein. Accordingly, compared to the case where the plug 50 has the gas passage that linearly extend in the up-down direction, electrical discharge is unlikely to occur when the gas passes through the gas passage 52.

Of course, the present invention is not limited by the above-described embodiment, and the present invention can be carried out in various forms as long as the forms belong to the technical scope of the present invention.

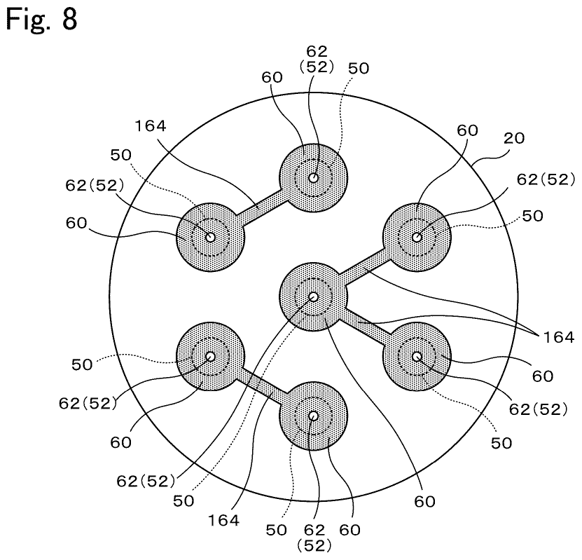

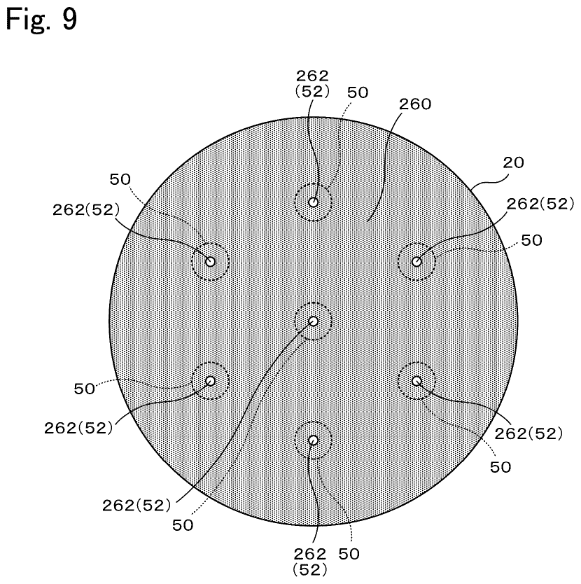

Although the conductive link 64 or the conductive link 66 provided on the lower surface of the ceramic plate 20 is utilized when any one of the plurality of conductive films 60 is electrically connected to at least one of the other conductive films 60 according to the above-described embodiment, the connection of the conductive film 60 is not limited to this. For example, as illustrated in FIG. 8, linear conductive links 164 provided on the lower surface of the ceramic plate 20 may be utilized. Alternatively, as illustrated in FIG. 9, a large conductive film 260 that has a size containing the plurality of conductive films 60 (for example, a size covering the entirety of the lower surface of the ceramic plate 20) may be formed on the lower surface of the ceramic plate 20. The large conductive film 260 has through holes 262 at positions facing the gas passages 52. In this case, the large conductive film 260 can be regarded as a conductive film including the plurality of conductive films 60 and a remaining portion other than the plurality of conductive films 60. The remaining portion serves as the conductive links. Referring to FIGS. 8 and 9, the same elements as the elements of the above-described embodiment are denoted by the same reference numerals. Alternatively, instead of the conductive links 64 and 66, wiring provided not on the lower surface of the ceramic plate 20 but inside the ceramic plate 20 may be utilized.

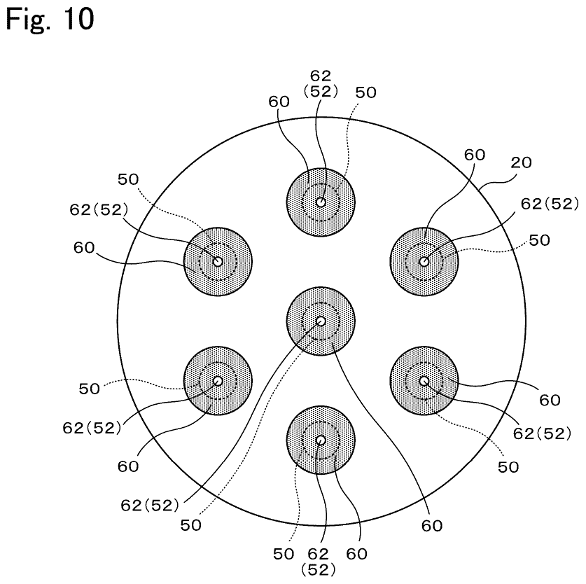

Any one of the plurality of conductive films 60 is electrically connected to at least one of the other conductive films 60 according to the above-described embodiment. Unlike this, the plurality of conductive films 60 may be independently provided as described in FIG. 10. That is, each of the plurality of conductive films 60 is not necessarily electrically connected to another conductive film 60. In this case, in the wafer placement table 10 in which the plug 50 has been replaced with the plug 50X, when the plug lower surface film 60Xa of the plug 50X and the annular film 60b around the plug lower surface film 60Xa are separated from each other by the ring-shaped gap 60Xc as illustrated in FIG. 6C, the potential of the annular film 60b and the potential of the conductive plate 30 are not the same. Thus, there is a possibility of the occurrences of electrical discharge between the annular film 60b and the conductive plate 30. However, effects other than this can be obtained similarly to the effects of the above-described embodiment.

Although the plug 50 including the helical gas passage 52 exemplifies the insulative gas passage plug according to the above-described embodiment, the insulative gas passage plug is not limited to this. For example, a porous plug may be used instead of the plug 50. In this case, a minute-hole network in the porous plug serves as the gas passage that allows the gas to flow in the up-down direction.

Although the contact members 70 being different members from the conductive plate 30 are each adopted as the conductive connecting portion according to the above-described embodiment, a conductive connecting portion that is a one-piece component including the contact members 70 and the conductive plate 30 may be adopted.

Although each of the gas introduction paths 34 extending through the conductive plate 30 in the up-down direction exemplifies the gas introduction path according to the above-described embodiment, the gas introduction path is not particularly limited to this. For example, instead of the small diameter portions 34b, the following ring path and entrance path may be provided: the ring path that is concentric with the conductive plate 30 in plan view and connects the plurality of large diameter portions 34a to each other; and the entrance path through which the gas is supplied from the lower surface of the conductive plate 30 to the ring path. In this case, the gas introduction path includes the plurality of large diameter portions 34a, the ring path connecting the plurality of large diameter portions 34a to each other, and the entrance path communicating with the ring path.

Although the upper surfaces of the plugs 50 are flush with the reference surface 21c according to the above-described embodiment, the upper surfaces of the plugs 50 may be flush with top surfaces of the circular small projections 21b or positioned between the reference surface 21c and the top surfaces of the circular small projections 21b.

Although the through holes 62 are provided in the conductive films 60 according to the above-described embodiment, the conductive films 60 may be formed of the metal porous films or metal meshes instead of providing the through holes 62. Also in this way, each of the conductive film 60 can allow the gas to flow from the gas introduction path 34 to the gas passage 52 of the plug 50.

Although the ceramic plate 20 in which the plugs 50 are secured to the plug reception holes 24 is bonded to the conductive plate 30 in the manufacture of the wafer placement table 10 according to the above-described embodiment, this is not limiting. For example, the plugs 50 may be secured to the plug reception holes 24 after the ceramic plate 20 including the vacant plug reception holes 24 have been bonded to the conductive plate 30. Alternatively, bonding of the ceramic plate 20 including the vacant plug reception holes 24 to the conductive plate 30 and bonding of the plugs 50 to the plug reception holes 24 may be simultaneously performed.

Although the conductive mesh or the aggregated conductive fiber having stretchability in the up-down direction exemplifies each of the contact members 70 according to the above-described embodiment, the contact member 70 is not particularly limited to this. For example, a conductive coil spring having stretchability in the up-down direction may serve as the contact member 70.

Although the contact members 70 have stretchability in the up-down direction according to the above-described embodiment, the contact members 70 are not particularly limited to this. For example, a contact member 70 may be a combination of a member having stretchability in an up-down direction and a bulk member not having stretchability. This can also maintain electrical connection between the conductive films 60 and the conductive plate 30 in a good state. Alternatively, the contact members 70 may be bulk members not having stretchability. However, in this case, electrical connection between the conductive films 60 and the conductive plate 30 may become difficult.

Although the dense plugs 50 having the helical gas passages 52 therein are used according to the above-described embodiment, porous plugs may be used instead of these plugs 50. In this case, a minute-hole network in each of the porous plugs serves as the gas passage that allows the gas to flow in the up-down direction. A zigzag gas passage may be provided instead of the helical gas passage 52.

Although the electrostatic electrode is included as the electrode 22 in the ceramic plate 20 according to the above-described embodiment, a heater electrode (resistance heating element) may be included in the ceramic plate 20 instead of or in addition to the electrostatic electrode. In this case, a heater power source is connected to the heater electrode. The ceramic plate 20 may include therein a single layer of the electrode or two or more layers of electrodes spaced from each other.

Lift pin holes extending through the wafer placement table 10 may be provided according to the above-described embodiment. Lift pins used to move up and down the wafer W relative to the wafer placement surface 21 are inserted through the lift pin holes. For example, when the wafer W is supported by three lift pins, three lift pin holes are provided.

The ceramic plate 20 is created by hot-press firing the molded body of the ceramic powder according to the above-described embodiment. The molded body may be created by laminating a plurality of tape molded bodies, by a mold casting, or by pressing and compacting the ceramic powder.

International Application No. PCT/JP2024/010541, filed on Mar. 18, 2024, is incorporated herein by reference in its entirety.

What is claimed is:

1. A wafer placement table comprising:
a ceramic plate having a wafer placement surface at an upper surface thereof, the ceramic plate including an electrode therein;
a conductive plate provided on a lower surface of the ceramic plate;
a resin layer joining the ceramic plate and the conductive plate to each other;
an insulative gas passage plug provided in a ceramic plate through portion extending through the ceramic plate, the insulative gas passage plug allowing gas to pass therethrough in an up-down direction;
a resin layer through portion provided at a position facing the insulative gas passage plug in the resin layer so as to extend through the resin layer, the resin layer through portion being larger than the insulative gas passage plug in plan view;
a gas introduction path provided in the conductive plate, the gas introduction path communicating with the insulative gas passage plug via the resin layer through portion;
a conductive film provided at a position facing the resin layer through portion in the lower surface of the ceramic plate, the conductive film being larger than the resin layer through portion in plan view, the conductive film allowing the gas to flow from the gas introduction path to the insulative gas passage plug; and
a conductive connecting portion provided in the gas introduction path, the conductive connecting portion being smaller than the resin layer through portion in plan view, the conductive connecting portion electrically connecting the conductive film and the conductive plate to each other, the conductive connecting portion allowing the gas to flow from the gas introduction path to the insulative gas passage plug.

2. The wafer placement table according to claim 1,
a wherein a plurality of the ceramic plate through portions are provided in the ceramic plate,
a a plurality of the insulative gas passage plugs are respectively provided in the plurality of ceramic plate through portions,
a a plurality of the gas introduction paths are provided at positions that respectively face the plurality of insulative gas passage plugs,
a a plurality of the resin layer through portions are provided at positions that respectively face the plurality of insulative gas passage plugs,
a a plurality of the conductive films are provided at positions respectively face the plurality of resin layer through portions, and
a a plurality of the conductive connecting portions are respectively provided in the plurality of the gas introduction paths, and
a wherein any one of the plurality of conductive films is electrically connected to at least one other conductive film.

3. The wafer placement table according to claim 2,
a wherein the any one of the plurality of conductive films is electrically connected to the at least one other conductive film via a conductive link provided on the lower surface of the ceramic plate.

4. The wafer placement table according to claim 2,
a wherein, in at least one of the plurality of conductive films, a plug lower surface film provided on a lower surface of a corresponding one of the plurality of insulative gas passage plugs and an annular film provided at an outer circumference of the plug lower surface film are separated from each other, and
a wherein the annular film is electrically connected to the conductive plate via the at least one other conductive film.

5. The wafer placement table according to claim 1,
a wherein the conductive connecting portion is a different member from the conductive plate.

6. The wafer placement table according to claim 5,
a wherein the conductive connecting portion includes a member having stretchability, and the member having stretchability is pressed by a lower surface of the insulative gas passage plug so as to be disposed in a compressed state.

7. The wafer placement table according to claim 1,
a wherein the insulative gas passage plug is a porous body, or the insulative gas passage plug is a dense body having a helical gas passage or a zigzag gas passage therein.
